(19) United States
(12) Patent Application Publication
(10) Pub. No.: US 2010/0302830 A1
(43) Pub. Date: Dec. 2, 2010

(54) SEMICONDUCTOR MEMORY DEVICE

(76) Inventor: Jong Hyun WANG, Chungcheongbuk-do (KR)

Correspondence Address: IP & T GROUP LLP, 7700 Little River Turnpike, Suite 207, Annandale, VA, 22003, US

(21) Appl. No.: 12/650,091

(22) Filed: Dec. 30, 2009

(30) Foreign Application Priority Data
May 29, 2009 (KR) 10-2009-0047816

(51) Int. Cl. G11C 5/06; G11C 7/00

(52) U.S. Cl. 365/63; 365/191

(57) ABSTRACT

A semiconductor memory device having a number of chips, each of the chips including a chip enable detection unit configured to simultaneously output a first signal and a second signal in response to a chip enable signal, a chip operation detection unit configured to output an operation state signal in response to the first signal, and an internal circuit configured to operate in response to a power source voltage and a control signal in response to the second signal being received.

### CROSS-REFERENCE TO RELATED APPLICATION

Priority to Korean patent application number 10-2009-0047816 filed on May 29, 2009, the entire disclosure of which is incorporated by reference herein, is claimed.

### BACKGROUND

One or more embodiments of the present invention relate to a semiconductor memory device and, more particularly, to semiconductor memory chips having a reduced number of pins outputting operation state signals.

Recently, in line with the user's needs, semiconductor devices have been reduced in size and weight. Accordingly, with a reduction in the size of the semiconductor devices, semiconductor memory devices in which a number of memory chips are formed in a single semiconductor package are being developed.

Each of the memory chips includes an internal circuit, including memory cells configured to store data and peripheral circuits configured to transfer driving voltages. The internal circuit is operated in response to a power source voltage, a chip enable signal, and a number of control signals. The control signals are used to control the respective memory chips, and they can include, for example, an address latch enable signal.

A number of pins configured to exchange I/O signals with external devices are arranged outside of the semiconductor package including the memory chips.

FIG. 1 is a diagram illustrating a conventional semiconductor package.

Referring to FIG. 1, the semiconductor package 10 includes a number of memory chips M1 to Mn (where ‘n’ is a natural number). Recently, the semiconductor package 10 has been fabricated to include 2, 4 or 8 memory chips. Pins CE1 to CEn, CTRL, RBs, and IOs are configured to transfer a number of I/O signals, including a power source voltage Vcc, and extend outside of the semiconductor package 10. For example, a number of the pins can include pins through which the first to n^{th} chip enable signals CE1 to CEn are supplied, pins through which the control signals CTRL are supplied, pins from which first to n^{th} operation state signals RB1 to RBn are outputted, and pins through which I/O signals IOs are inputted and outputted. The pins are electrically coupled to the memory chips M1 to Mn through wires.

The first to n^{th} operation state signals RB1 to RBn are not controlled by the chip enable signals CE1 to CEn unlike other signals. Thus, the number of pins from which the operation state signals RBs are outputted is identical to the number of memory chips. When each memory chip operates, it outputs a corresponding operation state signal.

However, with an increase in the number of pins from which the operation state signals RBs are outputted, it has become difficult to individually wire the pins. In particular, an increase in the number of pins can limit a desired reduction in the size of the semiconductor devices.

### BRIEF SUMMARY

According to embodiments of the present invention, operation state signals generated by a number of memory chips included in a package are controlled by chip enable signals, and the operation state signals are classified into at least one group and then wired. Accordingly, the number of pins from which the operation state signals are outputted can be reduced.

A semiconductor memory device having a number of chips, each of the chips according to an embodiment of the present invention includes: a chip enable detection unit configured to simultaneously output a first signal and a second signal in response to a chip enable signal, a chip operation detection unit configured to output an operation state signal in response to the first signal, and an internal circuit configured to operate in response to a power source voltage and a control signal in response to the second signal being received.

A semiconductor memory device according to another aspect of the present disclosure includes: a number of memory chips, chip enable detection units included in the respective memory chips and each configured to simultaneously output a first signal and a second signal in response to a chip enable signal, chip operation detection units included in the respective memory chips and each configured to output an operation state signal in response to the first signal, and internal circuits included in the respective memory chips and each configured to operate in response to the second signal and to output input/output (I/O) signals, and wires coupled to the respective memory chips and configured to transfer the respective operation state signals, the wires being bundled into groups.

Each chip enable detection unit includes a terminal to which the chip enable signal is supplied, the terminal being electrically coupled to a pin for the respective chip enable signal, the pin extending outside of the semiconductor memory device.

Each chip operation detection unit includes a terminal from which the respective operation state signal is outputted, the terminal being electrically coupled to a pin for the operation state signal, the pin extending outside of the semiconductor memory device.

If the wires are bundled into a single wire group, then the wire group is coupled to a pin for the one operation state signal.

If the wires are bundled into a number of groups, pins for the operation state signals are equal in number to the number of groups, and each pin for the respective operation state signal extends outside of the semiconductor package.

Each of the internal circuits includes a memory cell array and peripheral circuits, the internal circuits include different wires through which control signals and I/O signals are inputted and outputted.

A semiconductor memory device according to yet another aspect of the present disclosure includes: a number of memory chips included in one package and coupled to respective pins of the package through respective wires, chip enable detection units included in the respective memory chips and each configured to simultaneously output a first signal and a second signal in response to a chip enable signal, chip operation detection units included in the respective memory chips and each configured to output an operation state signal in response to the first signal, and internal circuits included in the respective memory chips and each configured to operate in response to the second signal, the operation state signals outputted from the respective memory chips being grouped.

If the operation state signals are grouped, then wires through which the operation state signals are transferred are bundled into at least one group. The package includes pins configured to output the operation state signals and the number of pins is equal to the number of groups.

### BRIEF DESCRIPTION OF THE DRAWINGS

FIG. 1 is a diagram illustrating a conventional semiconductor package;

FIG. 2 is a diagram illustrating a memory chip according to an embodiment of the present invention;

FIG. 3 is a diagram illustrating a semiconductor package according to an embodiment of the present invention;

FIG. 4 is a diagram illustrating a semiconductor package according to another embodiment of the present invention; and

FIG. 5 is a diagram illustrating multi-memory chips according to an embodiment of the present invention.

### DESCRIPTION THE INVENTION

Hereinafter, embodiments of the present invention are described in detail with reference to the accompanying drawings. The drawing figures are provided to allow those having ordinary skill in the art to understand the scope of the embodiments of the present invention.

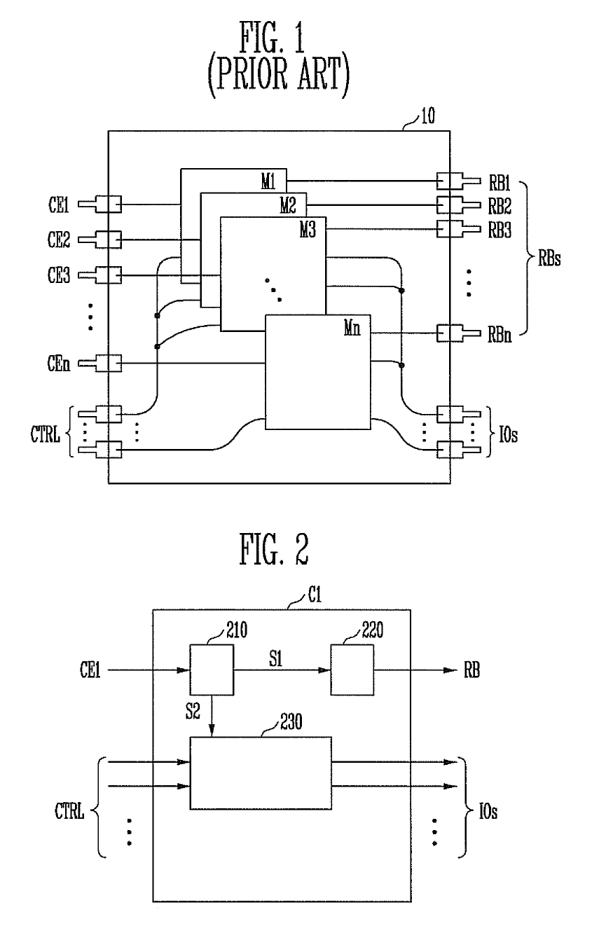

FIG. 2 is a diagram illustrating a memory chip according to an embodiment of the present invention.

Referring to FIG. 2, the memory chip C1 includes a chip enable detection unit 210, a chip operation detection unit 220, and an internal circuit 230. When a chip enable signal CE1 is supplied to the memory chip C1, the chip enable detection unit 210 outputs a first signal S1 to the chip operation detection unit 220 and a second signal S2 to the internal circuit 230. To this end, the chip enable detection unit 210 includes a terminal to which the chip enable signal CE1 is supplied. In response to the first signal S1, the chip operation detection unit 220 outputs an operation state signal RB indicating that the memory chip C1 is operating. To this end, the chip operation detection unit 220 includes a terminal from which the operation state signal RB is outputted. The internal circuit 230 includes a memory cell array and peripheral circuits. The internal circuit 230 is configured to perform I/O operations in response to the second signal S2, a control signal CTRL, and I/O signals IOs.

FIG. 3 is a diagram illustrating a semiconductor package according to an embodiment of the present invention.

Referring to FIG. 3, the semiconductor package 300 can include one or more memory chips C1 to Cn (where ‘n’ is a natural number). Recently, with the high degree of integration of semiconductor devices, a package, including a multi-memory chip having the memory chips C1 to Cn implemented in the single semiconductor package 300, is now being manufactured.

A number of pins extend outside of the semiconductor package 300. The pins are coupled to the memory chips C1 to Cn through wires. The pins can include, for example, pins for chip enable signals CE1 to CEn, including a power source voltage Vcc, pins for control signals CTRL, a pin for an operation state signal RB, and pins for I/O signals IOs. In particular, the memory chips C1 to Cn output respective operation state signals RB1 to RBn. Wires through which the operation state signals RB1 to RBn are transferred can be bundled into one group and coupled to one pin. For example, when the first chip enable signal CE1 is enabled, the first memory chip C1 operates. At this time, the first memory chip C1 outputs an operation state signal RBn. The outputted operation state signal RBn is outputted to the one pin for the operation state signal RB via a corresponding wire. Accordingly, the operation state of the first memory chip CE1 can be checked. As another example, when both the first and second memory chips C1 and C2 operate, the operation state signals RB1 and RB2 are outputted to the one pin for the operation state signal RB. Accordingly, the states of the first and second memory chips C1 and C2 can be checked based on the operation state signal RB.

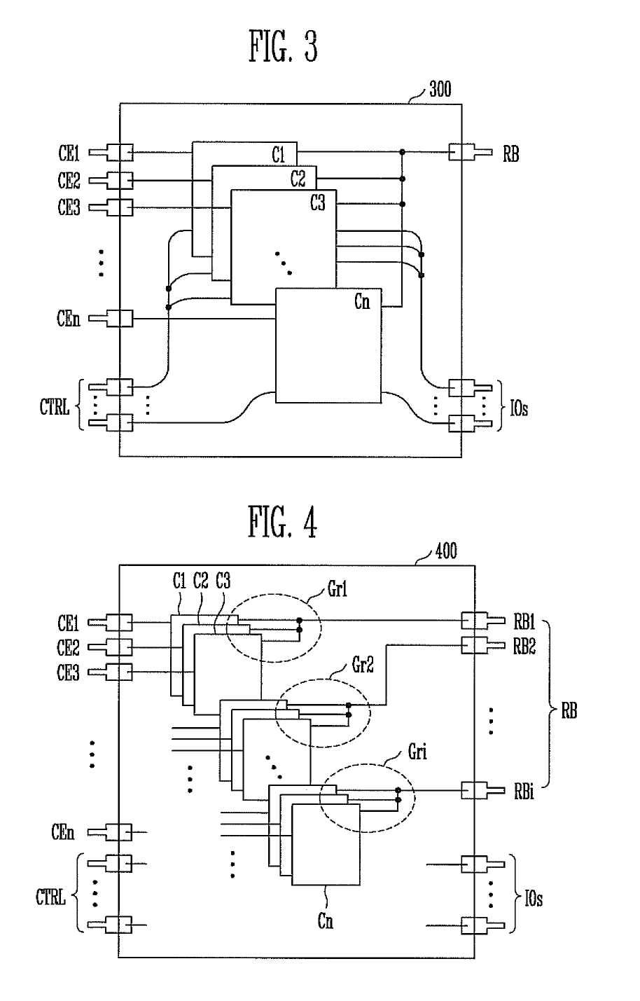

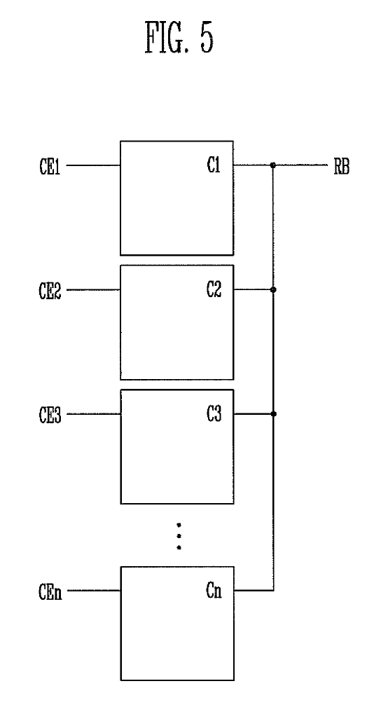

FIG. 4 is a diagram illustrating a semiconductor package according to another embodiment of the present invention.

Referring to FIG. 4, the semiconductor package 400 can include a number of grouped memory chips C1 to Cn (where ‘n’ is a natural number). A number of pins extend outside of the semiconductor package 400. The pins are coupled to the memory chips through respective wires. The pins can include, for example, pins for chip enable signals CE1 to CEn, including a power source voltage Vcc, pins for control signals CTRL, pins for operation state signals RB1 to RB1, and pins for I/O signals IOs.

In particular, the memory chips output respective operation state signals. Wires coupled to the respective memory chips can be bundled into several groups, and the wire groups can be coupled to different pins. For example, in the case in which three memory chips are bundled into one group, the wires from which the operation state signals are outputted are also bundled into groups each including three wires. Accordingly, first to i^{th} operation state signal output groups Gr1 to Gri (where ‘i’ is a natural number) can be formed, and the operation state signals RB1 to RBi can be outputted through the respective wire groups.

For example, when the second chip enable signal CE2 and the fourth chip enable signal CE4 are enabled, the operation states of selected memory chips can be checked based on the first operation state signal RB1 of the first operation state signal output group GR1 and the second operation state signal RB2 of the second operation state signal output group GR2.

As described above, when wires from which the operation state signals RB of the memory chips are outputted are bundled into groups and pins extending outside of the semiconductor package 400 are coupled to the respective groups, the operation states of memory chips can be checked individually or as a group. In particular, since the number of pins from which the operation state signals RB are outputted can be reduced, a semiconductor package can be further reduced in size. Furthermore, from a user's point of view, a burden to individually wire pins from which the operation state signals are outputted can be reduced.

FIG. 5 is a diagram illustrating multi-memory chips according to an embodiment of the present invention.

Referring to FIG. 5, a number of signals (e.g., chip enable signals, a power source voltage, control signals, an operation state signal, and I/O signals) are inputted to and outputted from each of the multi-memory chips C1 to Cn. Of the signals, only the chip enable signals CE1 to CEn and the operation state signal RB are described below.

When the chip enable signals CE1 to CEn are enabled, internal circuits (i.e., circuit units, each including a memory cell array and peripheral circuits) included in respective selected memory chips are operated. At this time, the memory chips output operation state signals, and the operation states of the memory chips can be checked. In particular, wires through which the operation state signals RB are outputted from the respective memory chips C1 to Cn can be bundled into groups. When the wires are bundled into the groups, the memory chips C1 to Cn output the respective operation state signals to the same node. Accordingly, when the wire groups from which the operation state signals are outputted are coupled to the pin of each semiconductor package, the size of the semiconductor package can be reduced.

As described above, operation state signals generated by a number of memory chips included in a package are controlled by chip enable signals, and the operation state signals are classified into at least one group and then wired. Accordingly, the number of pins from which the operation state signals are outputted can be reduced. Consequently, the size of a semiconductor package can be reduced, and a user can feel less uncomfortable to wire the pins from which the operation state signals are outputted.

What is claimed is:

1. A semiconductor memory device having a number of chips, each of the chips comprising:
a chip enable detection unit configured to simultaneously output a first signal and a second signal in response to a chip enable signal;
a chip operation detection unit configured to output an operation state signal in response to the first signal; and
an internal circuit configured to operate in response to a power source voltage and a control signal in response to the second signal being received.

2. The semiconductor memory device of claim 1, wherein each chip enable detection unit comprises a terminal supplied with the respective chip enable signal.

3. The semiconductor memory device of claim 2, wherein each terminal is electrically coupled to a pin for the respective chip enable signal, the pin extending outside of the semiconductor memory device.

4. The semiconductor memory device of claim 1, wherein each chip operation detection unit comprises a terminal for outputting the operation state signal.

5. The semiconductor memory device of claim 4, wherein each terminal is electrically coupled to a pin for the respective operation state signal, the pin extending outside of the semiconductor memory device.

6. The semiconductor memory device of claim 1, wherein each of the internal circuits comprises a memory cell array and peripheral circuits.

7. The semiconductor memory device of claim 1, wherein each of the internal circuits comprise wires for inputting and outputting control signals and I/O signals.

8. A semiconductor memory device, comprising:
a number of memory chips;
chip enable detection units included in the respective memory chips and each configured to simultaneously output a first signal and a second signal in response to a chip enable signal;
chip operation detection units included in the respective memory chips and each configured to output an operation state signal in response to the first signal; and
internal circuits included in the respective memory chips and each configured to operate in response to the second signal and to output input/output (I/O) signals,
wherein wires coupled to the respective memory chips and configured to transfer the respective operation state signals are bundled into groups.

9. The semiconductor memory device of claim 8, wherein each chip enable detection unit comprises a terminal supplied with the respective chip enable signal.

10. The semiconductor memory device of claim 9, wherein each terminal is electrically coupled to a pin for the respective chip enable signal, the pin extending outside of the semiconductor memory device.

11. The semiconductor memory device of claim 8, wherein each chip operation detection unit comprises a terminal for outputting the operation state signal.

12. The semiconductor memory device of claim 11, wherein each terminal is electrically coupled to a pin for the respective operation state signal, the pin extending outside of the semiconductor memory device.

13. The semiconductor memory device of claim 8, wherein a single wire group is coupled to a pin for one operation state signal upon the wires being bundled into the single wire group.

14. The semiconductor memory device of claim 8, wherein a number of pins for the operation state signals is equal to a number of groups upon the wires being bundled into the number of groups.

15. The semiconductor memory device of claim 13, wherein the pin for the operation state signal includes a pin extending outside of the semiconductor package.

16. The semiconductor memory device of claim 8, wherein each of the internal circuits comprises a memory cell array and peripheral circuits.

17. The semiconductor memory device of claim 8, wherein each of the internal circuits comprise the wires for inputting and outputting control signals and I/O signals.

18. A semiconductor memory device, comprising:
a number of memory chips included in one package and coupled to respective pins of the package through respective wires;
chip enable detection units included in the respective memory chips and each configured to simultaneously output a first signal and a second signal in response to a chip enable signal;
chip operation detection units included in the respective memory chips and each configured to output an operation state signal in response to the first signal; and
an internal circuit included in the respective memory chips, each internal circuit configured to operate in response to the second signal,
wherein the respective memory chips output operation state signals, the operation state signals being grouped together.

19. The semiconductor memory device of claim 18, wherein wires through which the operation state signals are transferred are bundled into at least one group.

20. The semiconductor memory device of claim 19, wherein the package comprises a number of pins configured to output the operation state signals, the number of pins being equal to the of number groups.
